(19) United States
(12) Patent Application Publication
(10) Pub. No.: US 2024/0274437 A1
(43) Pub. Date: Aug. 15, 2024

(54) METHODS OF FORMING STRUCTURES INCLUDING SILICON GERMANIUM AND SILICON LAYERS, DEVICES FORMED USING THE METHODS, AND SYSTEMS FOR PERFORMING THE METHODS

(71) Applicant: ASM IP Holding B.V., Almere (NL)

(72) Inventors: Amir Kajbafvala, Chandler, AZ (US); Joe Margetis, Gilbert, AZ (US); Xin Sun, Tempe, AZ (US); David Kohen, Phoenix, AZ (US); Dieter Pierreux, Dilbeek (BE)

(21) Appl. No.: 18/644,475

(22) Filed: Apr. 24, 2024

Related U.S. Application Data
(62) Division of application No. 17/141,360, filed on Jan. 5, 2021, now Pat. No. 11,996,289.
(60) Provisional application No. 63/011,215, filed on Apr. 16, 2020.

(51) Int. Cl. H01L 21/02; C23C 16/08; C23C 16/24; C23C 16/42; C23C 16/455; C23C 16/52; C30B 25/16; C30B 25/18; C30B 29/06; C30B 29/52; H01L 29/06; H01L 29/423; H01L 29/786

(52) U.S. Cl. CPC H01L 21/0262; C23C 16/08; C23C 16/24; C23C 16/42; C23C 16/45523; C23C 16/52; C30B 25/165; C30B 25/18; C30B 29/06; C30B 29/52; H01L 21/02507; H01L 21/02532; H01L 21/02576; H01L 21/02579; H01L 21/02603; H01L 29/0673; H01L 29/42392; H01L 29/78696

(57) ABSTRACT

Methods and systems for forming structures including one or more layers comprising silicon germanium and one or more layers comprising silicon are disclosed. Exemplary methods can include using a surfactant, using particular precursors, and/or using a transition step to improve an interface between adjacent layers comprising silicon germanium and comprising silicon.

### CROSS-REFERENCE TO RELATED APPLICATIONS

This application is a divisional of, and claims priority to, U.S. patent application Ser. No. 17/141,360 filed Jan. 5, 2021 titled METHODS OF FORMING STRUCTURES INCLUDING SILICON GERMANIUM AND SILICON LAYERS, DEVICES FORMED USING THE METHODS, AND SYSTEMS FOR PERFORMING THE METHODS; which claims the benefit of U.S. Provisional Patent Application No. 63/011,215, filed Apr. 16, 2020 and titled, METHODS OF FORMING STRUCTURES INCLUDING SILICON GERMANIUM AND SILICON LAYERS, DEVICES FORMED USING THE METHODS, AND SYSTEMS FOR PERFORMING THE METHODS, the disclosures of which are hereby incorporated by reference in their entirety.

### FIELD OF THE INVENTION

The present disclosure generally relates to methods suitable for forming electronic device structures, to systems for performing the methods, and to structures formed using the methods. More particularly, the disclosure relates to methods and systems for forming structures that include silicon layers and silicon germanium layers.

### BACKGROUND OF THE DISCLOSURE

Recently, three-dimensional devices, such as gate-all-around (GAA) or nanowire devices, have been developed in an effort to form high-performance devices with increased device density, with improved performance, and/or at lower costs.

During the formation of GAA devices, a stacked structure or superlattice of alternating layers comprising silicon germanium (SiGe layers) and layers comprising silicon (Si layers) can be formed by sequentially epitaxially growing the SiGe and Si layers on a surface of a substrate. Portions of these layers can be etched to form (e.g., silicon) wires that can form channel regions of GAA devices.

For many devices having Si layers epitaxially formed overlying SiGe layers, it is desirable to have a relatively small, abrupt, and consistent transition between a SiGe layer and a Si layer epitaxially formed thereon. Unfortunately, Ge on the surface of the SiGe layer is energetically more favorable than Si on the surface. Consequently, if the surface of the SiGe layer is not passivated prior to the subsequent Si layer growth, the Ge segregates, resulting in formation of an undesirably large interfacial or interface layer. Then, as a first monoatomic layer of Si is grown, Ge segregates again to the top layer. This mechanism can be repeated during the growth of the Si layer, creating an interfacial layer of a few tens of angstroms.

Accordingly, improved methods of forming structures with SiGe layers, such as structures including Si layers epitaxially grown overlying the SiGe layers, are desired.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

Various embodiments of the present disclosure relate to methods of forming structures, to structures and devices formed using such methods, and to apparatus for performing the methods and/or for forming the structures and/or devices. While the ways in which various embodiments of the disclosure address drawbacks of prior methods and structures are discussed in more detail below, in general, exemplary methods include techniques for forming a relatively thin and abrupt transition layer, which allows for formation of device structures with improved performance and/or devices with reduced performance variability.

In accordance with exemplary embodiments of the disclosure, a method of forming a structure is disclosed. Exemplary methods include providing a substrate within a reaction chamber, forming a first layer comprising silicon and germanium overlying a surface of the substrate, and forming a second layer comprising silicon overlying the first layer, wherein a surfactant precursor is provided to the reaction chamber during at least a portion of the step of forming the first layer. The surfactant is thought to contribute a species to the first layer that can mitigate migration of other species (e.g., germanium) within the first layer, thereby enabling a formation of an abrupt interface between the first layer and the second layer. In accordance with examples of the disclosure, the surfactant precursor comprises one or more of gallium, tellurium, antimony, indium, aluminum and/or tin. The surfactant precursor can include a halogen. For example, the surfactant precursor can be or include a halide, such as a chloride, bromide, or iodide. In accordance with some examples, the step of forming the first layer can include a first period comprising flowing the surfactant precursor, a second period (e.g., of lower or no flow of the surfactant precursor), and a third period comprising flowing a surfactant precursor, which can be the same as or different from the surfactant precursor flowed during the first period.

In accordance with additional embodiments of the disclosure, a method of forming a structure includes the steps of providing a substrate within a reaction chamber, forming a first layer comprising silicon and germanium overlying a surface of the substrate, and forming a second layer comprising silicon overlying the first layer, wherein, during the step of forming the first layer, a germanium precursor comprising a halogen is provided to the reaction chamber. For example, the germanium precursor can be or include a germanium halide or chlorohydride or chlorobromide. In accordance with further examples, the germanium precursor can include one or more of the group consisting of GeCl₄, GeClₓH₄₋ₓ. In accordance with further examples, two or more germanium precursors are provided to the reaction chamber during the step of forming the first layer. The step of forming the first layer can include a first period comprising flowing the germanium precursor, a second period comprising flowing a second germanium precursor, and a third period comprising flowing the germanium precursor. The second precursor can be or include, for example, a germane, such as germane or digermane. In accordance with further examples, two or more germanium precursors are flowed to the reaction chamber during the step of forming the first layer.

In accordance with additional embodiments of the disclosure, a method of forming a structure includes providing a substrate within a reaction chamber, forming a first layer comprising silicon and germanium overlying a surface of the substrate within the reaction chamber, providing one or more precursors to the reaction chamber for a transition period, and after the transition period, forming a second layer comprising silicon overlying the first layer within the reaction chamber. In accordance with examples of the disclosure, at least one of the one or more precursors are flowed to the reaction chamber during the step of forming the first layer. In accordance with further examples of the disclosure, a flowrate of the at least one of the one or more precursors is lower during the transition period relative to a flowrate of the at least one of the one or more precursors during the step of forming the first layer. In accordance with further examples, a germanium precursor is not provided to the reaction chamber during the transition period.

In accordance with further exemplary embodiments of the disclosure, a structure is formed using a method as described herein. The structure can include a substrate having a first layer overlying the substrate and a second layer overlying the first layer. The structure can include a plurality of layers comprising silicon and a plurality of layers comprising silicon germanium.

In accordance with yet additional embodiments of the disclosure, a device or portion thereof can be formed using a method and/or a structure as described herein.

In accordance with yet additional examples of the disclosure, a system to perform a method as described herein and/or to form a structure, device, or portion of either is disclosed.

These and other embodiments will become readily apparent to those skilled in the art from the following detailed description of certain embodiments having reference to the attached figures. The invention is not being limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates a method in accordance with exemplary embodiments of the disclosure.

FIG. 2 illustrates another method in accordance with exemplary embodiments of the disclosure.

FIG. 3 illustrates yet another method in accordance with exemplary embodiments of the disclosure.

FIG. 4 illustrates a structure in accordance with exemplary embodiments of the disclosure.

FIG. 5 illustrates a reactor system in accordance with additional exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, and reactor systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As set forth in more detail below, various embodiments of the disclosure provide methods for forming structures suitable for forming electronic devices. Exemplary methods can be used to, for example, form structures including one or more layers comprising silicon and one or more layers comprising silicon germanium, which are suitable for fabrication of, for example, gate-all around (GAA) or nanowire devices.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, such as a multi-port injection system, or the like, can be used for, e.g., sealing the reaction space, and can include a seal gas, such as a rare gas. In some cases, the term “precursor” can refer to a compound that participates in the chemical reaction that produces another compound. The term “inert gas” can refer to a gas that does not take part in a chemical reaction and/or does not become a part of a film to an appreciable extent. Exemplary inert (e.g., carrier or purge) gases include He, Ar, H₂, N₂, and any combination thereof.

As used herein, the term “substrate” can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as a Group II-VI or Group III-V semiconductor, and can include one or more layers overlying or underlying the bulk material. Further, the substrate can include various features, such as recesses, protrusions, and the like formed within or on at least a portion of a layer or surface of the substrate.

As used herein, the term “epitaxial layer” can refer to a substantially single crystalline layer upon an underlying substantially single crystalline substrate or layer.

As used herein, the term “chemical vapor deposition” can refer to any process wherein a substrate is exposed to one or more volatile precursors, which react and/or decompose on a substrate surface to produce a desired deposition.

As used herein, the term “silicon germanium” can refer to a semiconductor material comprising silicon and germanium and can be represented as Si₁₋ₓGeₓ wherein 1≥x≥0, or 0.8≥x≥0.1, or 0.6≥x≥0.2, or materials comprising silicon and germanium having compositions as set forth herein.

As used herein, the term “film” and/or “layer” can refer to any continuous or non-continuous structures and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous.

As used herein, the term “monocrystalline” may refer to a material that includes a substantial single crystal, i.e., a crystalline material that displays long range ordering. It should, however, be appreciated that a monocrystalline material may not be a perfect single crystal but may comprise various defects, stacking faults, atomic substitutions, and the like, as long as the monocrystalline material exhibits long range ordering.

As used herein, the term “non-monocrystalline” may refer to a material that does not comprise a substantial single crystal, i.e., a material which displays either short range ordering or no ordering of the crystalline structure. Non-monocrystalline materials may comprise polycrystalline materials which may display short range ordering and amorphous materials which may display substantially no ordering of the crystalline structure.

As used herein, a “structure” can include a substrate as described herein. Structures can include one or more layers overlying the substrate, such as one or more layers formed according to a method as described herein.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

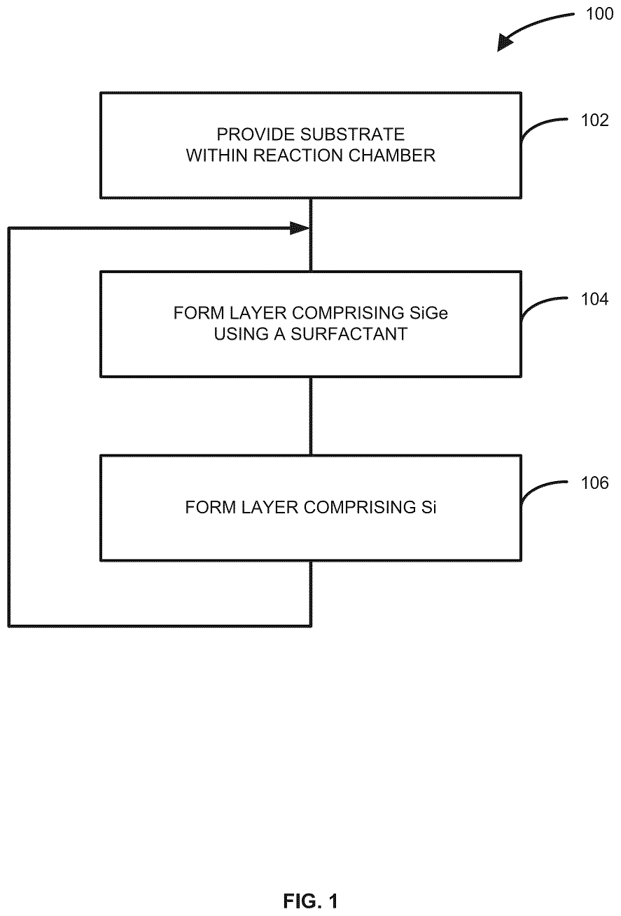

Turning now to the figures, FIG. 1 illustrates a method 100 in accordance with exemplary embodiments of the disclosure. Method 100 includes the steps of providing a substrate within a reaction chamber (step 102), forming a first layer comprising silicon and germanium overlying a surface of the substrate (step 104), and forming a second layer comprising silicon overlying the first layer (step 106). Steps 104 and 106 can be repeated a number of times as desired to form a stacked structure comprising one of more first layers alternating with one or more second layers. In accordance with examples of the disclosure, steps 104 and 106 can be repeated about 1 to about 2, about 1 to about 3, about 1 to about 4, or about 1 to about 6, or about 1 to 12 times.

During step 102, a substrate is provided within a reaction chamber. As a non-limiting example, the reaction chamber used during step 102 may comprise a reaction chamber of a chemical vapor deposition (e.g., epitaxial) system. However, it is also contemplated that other reaction chambers and alternative chemical vapor deposition systems may also be utilized to perform the embodiments of the present disclosure. The reaction chamber can be a stand-alone reaction chamber or part of a cluster tool.

Step 102 can include heating the substrate to a desired deposition temperature within the reaction chamber. In some embodiments of the disclosure, step 102 includes heating the substrate to a temperature of less than approximately 1100° C., or to a temperature of less than approximately 850° C., or to a temperature of less than approximately 700° C., or to a temperature of less than approximately 650° C., or to a temperature of less than approximately 600° C., or to a temperature of less than approximately 550° ° C., or to a temperature of less than approximately 500° C., or to a temperature of less than approximately 450° C., or to a temperature of less than approximately 400° C., or even to a temperature of less than approximately 300° C. For example, in some embodiments of the disclosure, heating the substrate to a deposition temperature may comprise heating the substrate to a temperature between approximately 400° ° C. and approximately 1100° C. or approximately 400° ° C. and approximately 700° C.

In addition to controlling the temperature of the substrate, a pressure within the reaction chamber may also be regulated. For example, in some embodiments of the disclosure, the pressure within the reaction chamber during step 102 may be less than 760 Torr, or less than 350 Torr, or less than 100 Torr, or less than 50 Torr, or less than 25 Torr, or less than 10 Torr, or even less than 5 Torr. In some embodiments, the pressure in the reaction chamber may be between 5 Torr and 760 Torr, between 10 Torr and 200 Torr, or between 10 Torr and 100 Torr. A temperature and/or pressure for steps 104 and/or 106 can be the same or similar to the temperature and/or pressure of step 102.

Step 104 of forming the first layer comprising silicon and germanium overlying a surface of the substrate can include flowing a silicon precursor and a germanium precursor to the reaction chamber. For example, a silicon precursor and a germanium precursor can be provided to a gas distribution assembly, e.g., through one or more gas injectors, such as multi-port injectors (MPIs), including a plurality of individual port injectors for providing a gas mixture into the reaction chamber. Various combinations of the precursors can be supplied to one or more of the individual port injectors to fine tune concentration profiles as desired. The silicon precursor and the germanium precursor can be provided to the reaction chamber, such that gas phases of the precursors are provided to the reaction chamber for an overlapping period. For example, both precursors can be provided to the reaction chamber for substantially the same period.

Exemplary silicon precursors include silanes and silicon halides. In some embodiments, the silicon halide compound can include, for example, a silicon halide having the general formula given as: SiₓW_{y}H_{z}, wherein “W” is a halide selected from the group consisting of Fluorine (F), Chlorine (Cl), Bromine (Br), and Iodine (I), “x” and “y” are integers greater than zero, and “z” is an integer greater than or equal to zero. In some embodiments, the silicon halide precursor may be selected from the group consisting of silicon fluorides (e.g., SiF₄), silicon chlorides (e.g., SiCl₄), silicon bromides (e.g., SiBr₄), and silicon iodides (e.g., SiI₄). In some embodiments, the silicon halide precursor may comprise silicon tetrachloride (SiCl₄). In some embodiments, the silicon halide precursor may comprise a silane, such as, for example, silane (SiH₄), disilane (Si₂H₆), trisilane (Si₃H₈), tetrasilane (Si₄H₁₀) or higher order silanes with the general empirical formula SiₓH(2ₓ₊₂).

By way of examples, the silicon precursor can be or include one or more of silicon tetrachloride (SiCl₄), trichloro-silane (SiCl₃H), dichlorosilane (SiCl₂H₂), monochlorosilane (SiClH₃), hexachlorodisilane (HCDS), octachlorotrisilane (OCTS), a silicon iodide, a silicon bromide; or an amino-based precursor, such as hexakis(ethylamino)disilane (AHEAD) and SiH[N(CH₃)₂]₃(₃DMASi), a bis(dialkylamino)silane, such as BDEAS (bis(diethylamino)silane); a mono(alkylamino)silane, such as di-isopropylaminosilane; or an oxysilanes-based precursor, such as tetraethoxysilane Si(OC₂H₅)₄.

In some cases, the silicon precursor can include two or more precursors, such as a halogenated precursor (e.g., a silicon halide compound noted above) and a silane precursor. By way of particular example, the silicon precursor can include dichlorosilane and silane.

Exemplary germanium precursors include germanes, such as germane (GeH₄), digermane (Ge₂H₆), trigermane (Ge₃H₈), or germylsilane (GeH(Si), and halogen compounds, such as GeBr₄ or other suitable germanium-containing precursor. By way of particular examples, the germanium precursor can include one or more of germane and germanium tetrachloride (GeCl₄) or GeClₓH₄₋ₓ.

Volumetric flow rates and flow ratios of the silicon precursor and the germanium precursor can vary in accordance with desired composition of the first layer. By way of examples, a flowrate of a silicon precursor can be about 10 sccm to about 700 sccm, or about 10 sccm to about 400 sccm, or about 10 sccm to about 200 sccm; a flowrate of a germanium precursor can be about 10 sccm to about 990 sccm, about 10 sccm to about 220 sccm, or about 10 sccm to about 85 sccm; either of which flowrates can be with or without a carrier gas.

In addition to the silicon precursor and the germanium precursor, a surfactant precursor can be provided to the reaction chamber for at least a portion (e.g., all or less than fifty percent) of step 104. The surfactant can passivate or facilitate passivation of a surface of the first layer. This is thought to reduce an amount of germanium that migrates to a surface of the first layer, which facilitates formation of thin, abrupt interfaces between silicon germanium and silicon layers.

Exemplary surfactant precursors may desirably include a relatively low energy atom (compared to germanium), which may additionally or alternatively not be significantly incorporated into the first layer as the first layer forms.

The surfactant precursor can include, for example, one or more of gallium, tellurium, antimony, indium, aluminum, and tin, such that one or more of gallium, tellurium, antimony, indium, aluminum and/or tin is incorporated into at least a portion of the first layer comprising silicon and germanium. Exemplary surfactant precursors can include a halogen, such as one or more of chlorine, bromine, or iodine. By way of particular examples, the surfactant precursor can include one or more of the group consisting of AlCl₃, GaCl₃, SnCl₄, SbCl₃, InCl₃.

In some embodiments, the surfactant precursor can comprise at least one metalorganic compound. Particular examples can include, for example, trimethylgallium (TMG) or triethylgallium (TEG), tritertiarybutylgallium (TTBGa), galliumtrichlorine (GaCl₃), Ga(BH₄)₃, diethylgallium chloride (DeGaCI), RGaCl₂, GaR₃, GaHx, wherein R can be, for example, an alkyl group, linear or branched, such as an ethyl, butyl, or propyl group. The aluminum dopant precursor can comprise at least one of trimethylaluminum (TMA) or triethylaluminum (TEA). The indium dopant precursor can comprise at least one of: trimethylindium (TMI), triethylindium (TEI), cyclopentadienylindium (InCp), di-isopropylmethylindium (DIPMeln), or ethyldimethylindium (EDMIn).

In some embodiments, the surfactant precursor may be provided in diluted form and the diluted form may comprise approximately 0.1% to approximately 100% surfactant precursor in a carrier gas (if present). Additionally or alternatively, a dilution gas or an inert gas, such as hydrogen, can be provided to the reaction chamber during one or more of steps 104 and 106. In some cases, the dilution or inert gas can be continuously flowed to the reaction chamber during steps 104, 106 and any repeating of steps 104, 106.

The surfactant precursor can be provided during all or a portion or portions of step 104. For example, the surfactant precursor can be provided only near an end (e.g., last 25% or 10% or 5%) of step 104, near a beginning of step 104 (e.g., first 25% or 10% or 5%), or both. In other cases, the surfactant precursor can be provided during substantially all of step 104. In some cases, a flowrate of the surfactant precursor can vary during step 104—e.g., the flowrate can be higher near the beginning and/or end of step 104, relative to the middle. In this context, beginning, middle, and end refer to a time sequence of step 104. By way of examples, step 104 can include a first period comprising flowing the surfactant precursor, a second period, and a third period comprising flowing the same or another surfactant precursor.

In some cases, step 104 can include (1) forming a silicon germanium layer (without an added surfactant) and (2) forming a silicon germanium layer with the added surfactant. In some cases, step 104 can include (1) forming a silicon germanium layer with an added surfactant, (2) forming a silicon germanium layer (without an added surfactant), and (3) forming a silicon germanium layer with the added surfactant.

The first layer may form as a crystalline (e.g., monocrystalline) material overlying at least a portion of the surface. Accordingly, at least a portion of the first layer may be monocrystalline and serve as a template for further epitaxial layers. In some cases, the entire first layer may be monocrystalline. In some cases, the first layer can form as non-monocrystalline material in some areas.

A thickness of the first layer formed during step 104 can be between greater than zero or about 2 nm and about 10 nm, between about 2 nm and about 20 nm, or between about 2 nm and about 100 nm.

The first layer can include about 70 to about 80 atomic percent, or about 70 to about 90 atomic percent, or about 70 to about 99 atomic percent silicon and/or about 1 to about 30 atomic percent, or about 5 to about 20 atomic percent, or about 15 to about 30 atomic percent or about 20 to about 30 atomic percent germanium. In some embodiments, the germanium content within the first layer may not be constant, but rather may be varied, such that the germanium content (and/or other component) may have a graded composition within the first layer.

Step 104 and/or step 106 can optionally include providing an etchant to the reaction chamber. An etchant can include, for example, a halogen, such as chlorine, bromine, iodine, hydrogen chloride, hydrogen bromide, or hydrogen iodide.

During step 106, a second layer comprising silicon is (e.g., epitaxially) formed overlying the first layer over at least a portion of the substrate. Precursors for the second layer comprising silicon can be the same or similar to the silicon precursors described above.

Step 106 can be performed in the same reaction chamber used during step 104. Alternatively, step 106 can be performed in another reaction chamber, such as another reaction chamber in the same cluster tool as the reaction chamber used during step 104 or of another reactor system. A temperature and/or pressure for step 106 can be the same or similar to the temperature and/or pressure described above in connection with step 104.

A thickness of the second layer formed during step 106 can be between greater than zero or about 2 nm and about 4 nm, between 2 nm and about 10 nm, between about 2 nm and about 20 nm, or between about 2 nm and about 100 nm.

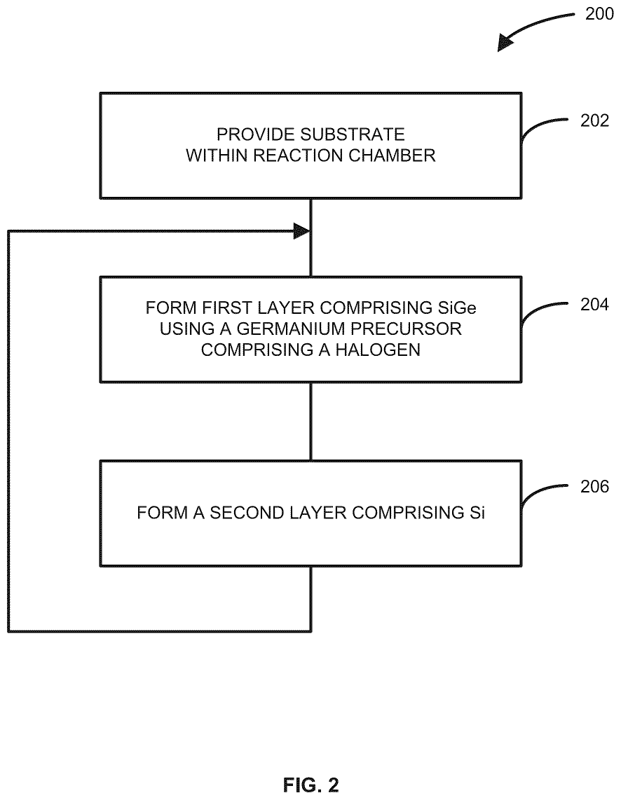

FIG. 2 illustrates another method in accordance with exemplary embodiments of the disclosure. Method 200 includes the steps of providing a substrate within a reaction chamber (step 202), forming a first layer comprising silicon and germanium overlying a surface of the substrate (step 204), and forming a second layer comprising silicon overlying the first layer (step 206). Method 200 can be similar to method 100, except method 200 may not necessarily include, but can include, providing a surfactant precursor to the reaction chamber during at least a portion of the step of forming the first layer (step 204), and method 200 includes providing a germanium precursor comprising a halogen during the step of forming the first layer (step 204). Use of a germanium precursor comprising a halogen (germanium halogen precursor) is thought to additionally or alternatively facilitate formation of an abrupt, relatively small interface layer.

The reaction chamber temperatures and pressures for steps 202-206 can be the same or similar to the temperatures and pressures noted above in connection with steps 102-106 of method 100. Further, the silicon and germanium precursors can be the same or similar to the silicon and germanium precursors noted above, except at least the germanium precursor provided during step 206 comprises a halogen.

Exemplary germanium precursors that include a halogen include germanium halides, and germanium halogen hydrides (e.g., germanium chlorohydrides, bromohydrides, or the like. Exemplary germanium halides include germanium chlorides, germanium bromides, and germanium iodides. By way of examples, the germanium precursor can be or include GeCl₄ or GeClₓH₄₋ₓ.

In accordance with examples of these embodiments, the germanium precursor can include two or more germanium precursors that can be provided to the reaction chamber during step 204. In these cases, at least one of the germanium precursors of the two or more germanium precursors includes a halogen. Further, the flow of the two or more germanium precursors to the reaction chamber can overlap in time—or not. For example, the step of forming the first layer can include a first period comprising flowing the (e.g., first) germanium precursor, a second period comprising flowing a second germanium precursor; and a third period comprising flowing a (e.g., first, second, or a third) germanium precursor. At least one or both of the first and third germanium precursors can include a germanium halogen precursor.

The additional germanium precursor(s) can include any of the germanium precursors noted herein, including non-halogen germanium precursors. By way of examples, the additional germanium precursor(s) can include a germane, such as germane.

When two or more germanium precursors are used, the germanium precursor comprising a halogen can be provided during all or a portion or portions of step 204. For example, the germanium halogen precursor can be provided only near an end (e.g., last 25% or 10% or 5%) of step 204, near a beginning of step 104 (e.g., first 25% or 10% or 5%), or both. In other cases, the germanium halogen can be provided during substantially all of step 204. In some cases, a flowrate of the germanium halogen precursor can vary during step 204—e.g., the flowrate can be higher near the beginning and/or end of step 204, relative to the middle. In this context, beginning, middle, and end refer to a time sequence of step 204. By way of examples, step 204 can include a first period comprising flowing the germanium halogen precursor, a second period, and a third period comprising flowing the same or another germanium halogen precursor.

In some cases, step 204 can include (1) forming a silicon germanium layer using a germanium halogen precursor and (2) forming a silicon germanium layer with or without use of a germanium halogen precursor. In some cases, step 204 can include (1) forming a silicon germanium layer using a germanium halogen precursor, (2) forming a silicon germanium layer with or without use of a germanium halogen precursor, and (3) forming a silicon germanium layer with the same or a different germanium halogen precursor.

Step 206 can be the same or similar to step 106 described above. Further, steps 204-206 can be repeated a desired number of times, such as the number of times noted above in connection with method 100.

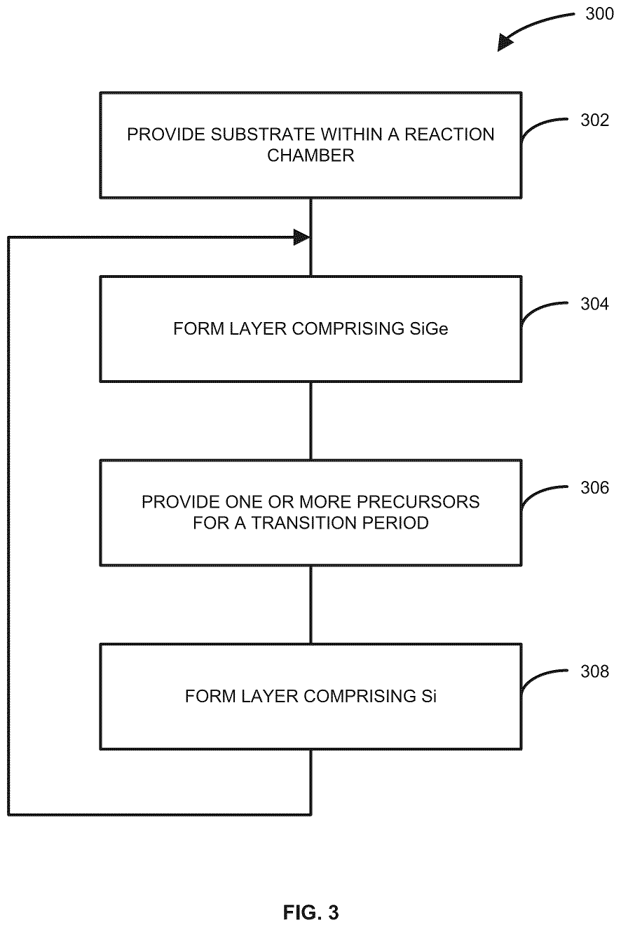

FIG. 3 illustrates another method 300 in accordance with examples of the disclosure. Method 300 includes the steps of providing a substrate within a reaction chamber (step 302), forming a first layer comprising silicon and germanium overlying a surface of the substrate within the reaction chamber (step 304), providing one or more precursors to the reaction chamber for a transition period (step 306), and after the transition period, forming a second layer comprising silicon overlying the first layer within the reaction chamber (step 308). Although illustrated in connection with method 300, method 100 and/or method 200 can include a transition step (step 306) as described herein.

Step 302 can be the same or similar to step 102 or 202 described above. Step 304 can be the same or similar to step 104 or 204 described above. Step 308 can be the same or similar to step 106 or 206 described above. The temperatures, pressures, precursors, flowrates, and resultant film thicknesses and compositions for each of these steps can be as described above. Further, steps 304-308 can be repeated a number of times as described herein.

As illustrated, method 300 includes an additional step 306 of providing one or more precursors to the reaction chamber for a transition period. Providing one or more precursors to the reaction chamber for a transition period step 306 facilitates formation of abrupt and/or relatively small interfaces between the silicon germanium and silicon layers. Further, step 306 allows for a reduction in process time and a corresponding increase in throughput, because purge steps that would typically be employed between steps 304 and 308 can be significantly reduced or otherwise eliminated. For example, an increase of 300-400% in throughput was achieved using method 300, compared to a similar method that relies on a typical purge process, rather than step 306.

In accordance with examples of the disclosure, a carrier gas, such as hydrogen, can be continuously flowed to the reaction chamber during one or more (e.g., all) of steps 304-308. With a typical process, the hydrogen alone is used to purge the reaction chamber between steps 304 and 308. Adding a precursor during step 306 significantly reduces purge/transition time and provides desired film properties that allow for an abrupt, thin interface between layers.

A pressure and temperature within the reaction chamber during step 306 can be the same or similar to the temperature and pressure during steps 304 and/or 308.

In accordance with examples of the disclosure, step 306 includes providing one or more precursors used to form the first layer. In other words, at least one of the one or more precursors are flowed to the reaction chamber during the step of forming the first layer. In some cases, step 306 can include flowing two or more precursors provided to the reaction chamber during step 304. For example, step 306 can include flowing a halogenated silicon precursor and a silane. Step 306 can additionally include providing an etchant, such as an etchant described herein, to the reaction chamber. If provided, the flowrate of the etchant and/or carrier gas used during step 306 can be lower than the flowrate of the etchant and/or carrier gas used during step 304.

In accordance with examples of the disclosure, a flowrate of the at least one of the one or more precursors is lower during the transition period relative to a flowrate of the at least one of the one or more precursors during the step of forming the first layer. In accordance with further examples, a germanium precursor is not provided to the reaction chamber during the transition period. In some cases, all of the gases provided during step 304, except the germanium precursor, can be supplied to the reaction chamber during step 306. The one or more precursors provided to the reaction chamber during step 306 can include a silicon precursor, such as a silicon precursor as described herein. In some cases, a carrier gas (e.g., hydrogen) and/or an etchant, whether or not provided to the reaction chamber during step 204, can be provided to the reaction chamber during step 306.

A duration of step 306 can vary according to various factors, including film thickness and composition. In accordance with examples of the disclosure, a duration of step 306 can be less than 20 seconds, less than 15 seconds, or less than 1 second.

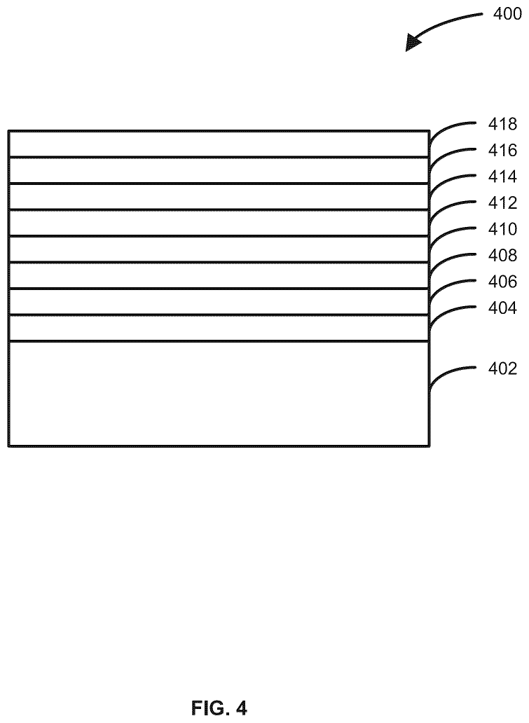

FIG. 4 illustrates a device structure (sometimes referred to simply as a structure) 400 formed in accordance with exemplary embodiments of the disclosure. Structure 400 includes a substrate 402 and a plurality of epitaxial layers 404-418 formed overlying substrate 402. In particular, structure 400 includes a plurality of epitaxial silicon germanium layers 404, 408, 412, and 416 alternating with a plurality of silicon layers 406, 410, 414, and 418. Epitaxial silicon germanium layers 404, 408, 412, and 416 can be formed, for example, using step 104, 204 or 304; epitaxial silicon layers 406, 410, 414, and 418 can be formed, for example, using step 106, 206 or 308 (with or without a transition period). Structure 400 can be used in the formation of three-dimensional devices, such as gate-all-around or nanowire devices.

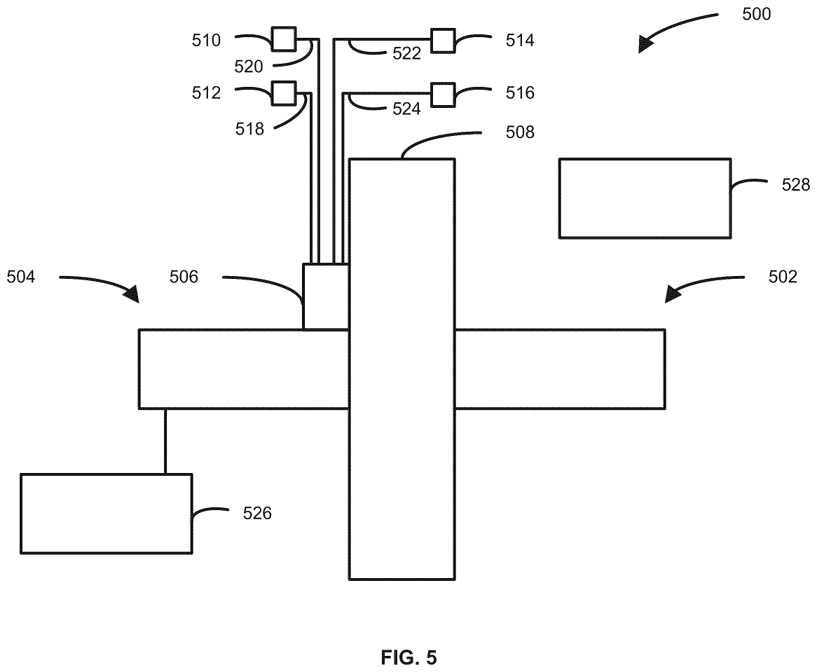

FIG. 5 illustrates a reactor system, or simply system, 500 in accordance with yet additional exemplary embodiments of the disclosure. System 500 can be used to perform a method as described herein and/or form a structure as described herein.

In the illustrated example, system 500 includes an optional substrate handling system 502, one or more reaction chambers 504, a gas injection system 506, and optionally a wall 508 disposed between reaction chamber(s) 504 and substrate handling system 502. System 500 can also include a first gas source 510, a second gas source 512, a third gas source 514, a fourth gas source 516, an exhaust source 526, and a controller 528.

Although illustrated with four gas sources 510-516, system 500 can include any suitable number of gas sources. Gas sources 510-516 can each include, for example, a silicon precursor source, a germanium precursor source, an etchant source and/or a carrier gas source, as described above. Gas sources 510-516 can be coupled to reaction chamber 504 via lines 518-524, which can each include flow controllers, valves, heaters, and the like.

System 500 can include any suitable number of reaction chambers 504 and substrate handling systems 502. Further, one or more reaction chambers 504 can be or include a cross-flow epitaxial reaction chamber.

Exhaust source 526 can include one or more vacuum pumps.

Controller 528 can be configured to perform various functions and/or steps as described herein. For example, controller 528 can be configured to control gas flow into the gas injection system to form a first layer overlying the substrate and forming a second layer overlying the first layer, and repeating such steps to form a structure, as described above. Controller 528 can include one or more microprocessors, memory elements, and/or switching elements to perform the various functions. Although illustrated as a single unit, controller 528 can alternatively comprise multiple devices. By way of examples, controller 528 can be used to control gas flow (e.g., by monitoring flow rates of precursors and/or other gases from sources 510-516 and/or controlling valves, motors, heaters, and the like). Further, when system 500 includes two or more reaction chambers, the two or more reaction chambers can be coupled to the same/shared controller.

During operation of reactor system 500, substrates, such as semiconductor wafers (not illustrated), are transferred from, e.g., substrate handling system 502 to reaction chamber 504. Once substrate(s) are transferred to reaction chamber 504, one or more gases from gas sources 510-516, such as precursors, carrier gases, etchants, and/or purge gases, are introduced into reaction chamber 504 via gas injection system 506. Gas injection system 506 can be used to meter and control gas flow of one or more gases (e.g., from one or more gas sources 510-516) during substrate processing and to provide desired flows of such gas(es) to multiple sites within reaction chamber 504.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements (e.g., step) described, may become apparent to those skilled in the art from the description. Such modifications and embodiments are also intended to fall within the scope of the appended claims.

What is claimed is:

1. A method of forming a structure, the method comprising the steps of:
providing a substrate within a reaction chamber;
forming a first layer comprising silicon and germanium overlying a surface of the substrate; and
forming a second layer comprising silicon overlying the first layer,
wherein, during the step of forming the first layer, a germanium precursor comprising a halogen is provided to the reaction chamber.

2. The method of claim 1, wherein the germanium precursor is selected from the group consisting of germanium halides or germanium chlorohydrides or germanium bromohydrides.

3. The method of claim 1, wherein the germanium precursor is selected from one or more of the group consisting of GeCl₄ or GeClₓH₄₋ₓ.

4. The method of claim 1, wherein two or more germanium precursors are provided to the reaction chamber during the step of forming the first layer.

5. The method of claim 1, wherein the step of forming the first layer comprises:
a first period comprising flowing the germanium precursor;
a second period comprising flowing a second germanium precursor; and
a third period comprising flowing the germanium precursor.

6. The method of claim 5, wherein the second precursor comprises a germane.

7. The method of claim 1, wherein two or more germanium precursors are flowed to the reaction chamber during a portion of the step of forming the first layer.

8. A method of forming a structure, the method comprising the steps of:
providing a substrate within a reaction chamber;
forming a first layer comprising silicon and germanium overlying a surface of the substrate within the reaction chamber;
providing one or more precursors to the reaction chamber for a transition period; and
after the transition period, forming a second layer comprising silicon overlying the first layer within the reaction chamber.

9. The method of claim 8, wherein at least one of the one or more precursors are flowed to the reaction chamber during the step of forming the first layer.

10. The method of claim 9, wherein a flowrate of the at least one of the one or more precursors is lower during the transition period relative to a flowrate of the at least one of the one or more precursors during the step of forming the first layer.

11. The method of claim 8, wherein a germanium precursor is not provided to the reaction chamber during the transition period.

12. The method of claim 8, wherein the one or more precursors comprise a silicon precursor.

13. A device structure formed according to the method of claim 1.

14. The device structure of claim 13, wherein the device structure comprises a nanowire.

15. A reactor system comprising:
one or more reaction chambers;
a gas injection system fluidly coupled to at least one of the one or more reaction chambers;
a first gas source;
a second gas source;
a third gas source;
an exhaust source; and
a controller,
wherein the controller is configured to control gas flow into the gas injection system to selectively form a layer comprising silicon and germanium overlying the substrate and layer comprising silicon overlying the layer comprising silicon and germanium according to the method of claim 1.
